(19) United States
(12) Patent Application Publication
(10) Pub. No.: US 2011/0075360 A1
(43) Pub. Date: Mar. 31, 2011

(54) ELECTRONIC APPARATUS

(76) Inventors: Kentaro Tomioka, Sayama-shi (JP); Takeshi Hongo, Sagamihara-shi (JP); Yukihiko Hata, Hamura-shi (JP)

(21) Appl. No.: 12/837,846

(22) Filed: Jul. 16, 2010

(30) Foreign Application Priority Data
Sep. 30, 2009 (JP) 2009-228908

(51) Int. Cl. H05K 7/20

(52) U.S. Cl. 361/695; 361/700

(57) ABSTRACT

According to one embodiment, an electronic apparatus includes a housing, a heat dissipating member disposed inside the housing, a first heat generating element mounted on the circuit board, a second heat generating element mounted on the circuit board, a first heat pipe, and a second heat pipe. The first heat pipe includes a first heat receiving portion thermally connected to the first heat generating element, and a first heat releasing portion thermally connected to the heat dissipating member. The second heat pipe includes a second heat receiving portion thermally connected to the second heat generating element, a second heat releasing portion thermally connected to the heat dissipating member, and a fluid capturing structure configured to temporarily hold a working fluid enclosed inside the second heat pipe.

### CROSS-REFERENCE TO RELATED APPLICATIONS

This application claims priority from Japanese Patent Application No. 2009-228908 filed on Sep. 30, 2009, the entire content of which is incorporated herein by reference.

### BACKGROUND

1. Field

One embodiment of the invention relates to an electronic apparatus having a heat dissipation structure.

2. Description of the Related Art

In related art electronic apparatuses such as video recorders and personal computers, a heat generating element such as an LSI is mounted on a circuit board. To cool such a heat generating element, a cooling system including, for example, a heat pipe and a heat sink is used.

In the heat sink described in JP-A-2009-150561, an end portion of a first heat pipe or a second heat pipe is thermally connected to respective heat generating elements, and the other end portions of the first and second heat pipe are thermally connected to a plurality of fins. The first heat pipe and the second heat pipe have different areas of contact to the fins to efficiently cool the heat generating elements.

However, in the related art, no consideration is made to prevent reduction of cooling efficiency with respect to a sloped heat pipe. For example, in a case in which a heat pipe is arranged such that its heat receiving portion is positioned higher than its heat releasing portion, circulation of working fluid enclosed therein is obstructed as the slope of the heat pipe becomes steep. When a plurality of heat pipes are arranged on top of each other for high-density mounting, cooling efficiency may decrease in each of the heat pipes.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary perspective view of a Set-top box according to an embodiment of the invention:

FIG. 2 is an exemplary sectional view schematically illustrating an internal configuration of the Set-top box according to the embodiment of the invention;

FIG. 3 is an exemplary plan view of a fourth circuit board having first and second heat receiving blocks which are thermally connected to a heat sink.

FIG. 4 is an exemplary perspective view of the fourth circuit board having the first and second heat receiving blocks which are thermally connected to the heat sink and a heat dissipating plate which is thermally connected to FETs in the embodiment of the invention;

FIG. 5 is an exemplary rear view of the Set-top box schematically illustrating a relative positional relationship between first to fourth circuit boards, the heat sink, and an exhaust fan, which are arranged inside a housing in the embodiment of the invention;

FIG. 6 is an exemplary sectional view of the Set-top box schematically illustrating a positional relationship between the fan and the fourth circuit board which are arranged inside the housing in the embodiment of the invention; and

FIG. 7 is an exemplary sectional view of heat pipes used in the embodiment of the invention.

### DETAILED DESCRIPTION

Various embodiments according to the invention will be described hereinafter with reference to the accompanying drawings. In general, according to one embodiment of the invention, an electronic apparatus includes a housing, a heat dissipating member disposed inside the housing, a first heat generating element mounted on the circuit board, a second heat generating element mounted on the circuit board, a first heat pipe, and a second heat pipe. The first heat pipe includes a first heat receiving portion thermally connected to the first heat generating element, and a first heat releasing portion thermally connected to the heat dissipating member. The second heat pipe includes a second heat receiving portion thermally connected to the second heat generating element, a second heat releasing portion thermally connected to the heat dissipating member, and a fluid capturing structure configured to temporarily hold a working fluid enclosed inside the second heat pipe.

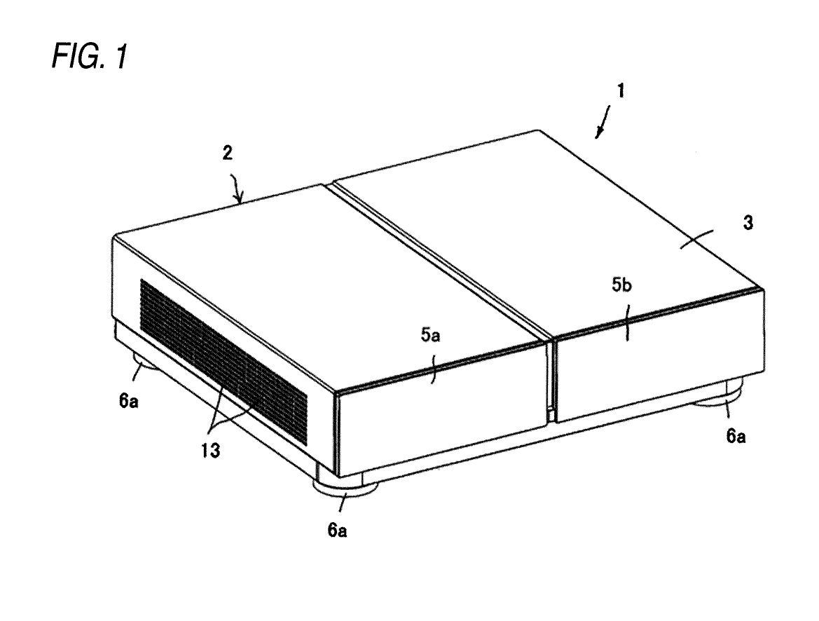

FIG. 1 illustrates a Set-top box 1 which is an example of an electronic apparatus. The Set-top box 1 is connected to a liquid crystal TV receiver in use, and has, for example, a function of receiving various TV programs and a function of recording a plurality of programs simultaneously or recording a long program.

The Set-top box 1 is has a flat box-shaped main body 2. The main body 2 includes a metal housing 4 which is covered with a decorative cover 3, and left and right front doors 5a, 5b which cover a front face of the decorative cover 3.

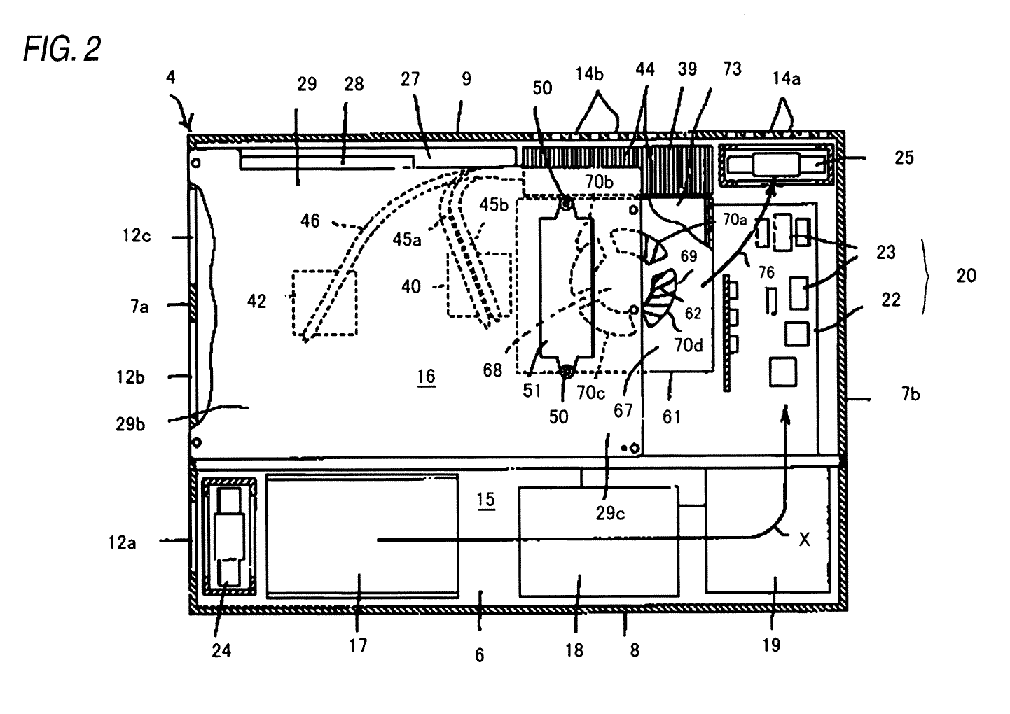

The housing 4 serves as a frame of the main body 2. As shown in FIGS. 2, 5, and 6. The housing 4 includes a bottom wall 6, left and right side walls 7a, 7b, a front wall 8, a back wall 9, and a top wall 10. The bottom wall 6 has a rectangular shape having four corner portions. Legs 6a are attached to the corner portions of the bottom wall 6, respectively, and are placed, for example, on a TV receiver rack. A rear half portion of the bottom wall 6 is formed with a plurality of air inlets 11 through a central portion thereof.

The side walls 7a, 7b, the front wall 8, and the back wall 9 are arranged upright from a perimeter of the bottom wall 6. The left side wall 7a has first to third intake holes 12a, 12b, 12c. The first to third intake holes 12a, 12b, 12c are arranged in line in the front-rear direction of the housing 4 at intervals, and communicate with the outside of the main body 2 via a plurality of vents 13 of the decorative cover 3.

A right half portion of the back wall 9 has a plurality of first air outlets 14a and a plurality of second air outlets 14b. The top wall 10 bridges over upper edges of the side walls 7a, 7b, the front wall 8, and the back wall 9, and is opposed to the bottom wall 6.

As shown in FIG. 2, the housing 4 has a first accommodation space 15 and a second accommodation space 16. The first accommodation space 15 has a front section which extends in the right-left direction of the housing 4 along the front wall 8 of the housing 4, and a rear section which extends in the front-rear direction of the housing 4 along the right side wall 7b. The first intake hole 12a of the side wall 7a communicates with a left part of the front section of the first accommodation space 15. The first air outlets 14a of the back wall 9 communicate with a rear part of the rear section of the first accommodation space 15.

The second accommodation space 16 is surrounded by the left side wall 7a and the back wall 9 of the housing 4, and is located behind the front section of the first accommodation space 15. The air inlets 11 of the bottom wall 6 communicate with a right part of the second accommodation space 16. The second intake hole 12b and the third intake hole 12b of the left side wall 7a communicate with a left part of the second accommodation space 16.

As shown in FIG. 2, a first information storage module 17, a second information storage module 18, a card connection device 19, and a power module 20 are disposed inside the first accommodation space 15 of the housing 4.

The first and second information storage modules 17, 18 serve to record TV programs and to play back the recorded TV program with quick search. The first information storage module 17 has, for example, two 5-inch hard disk drives. The second information storage module 18 has, for example, two 3.5-inch hard disk drives.

The card connection device 19 has, for example, six card slots into which six B-CAS cards for receiving ground-wave digital broadcasts, BS digital broadcasts, etc. are to be inserted. The first and second information storage modules 17, 18 and the card connection device 19 are disposed in the front section of the first accommodation space 15, and are arranged in line in the right-left direction of the housing 4.

The power module 20 has a first circuit board 22 which is a power board. The first circuit board 22 is fixed to a right end portion of the bottom wall 6 of the housing 4. The first circuit board 22 is mounted with a plurality of circuit components 23 forming a power circuit. The circuit components 23 include components that generate heat during operation. The circuit components 23 are disposed in the rear section of the first accommodation space 15.

A first axial flow fan 24 is disposed in the left end part of the front section of the first accommodation space 15. The first axial flow fan 24 serves to take air forcibly into the first accommodation space 15 from outside the housing 4, and is arranged to face the first intake hole 12a.

A second axial flow fan 25 is disposed in the rear end part of the rear section of the first accommodation space 15. The second axial flow fan 25 is an example of an exhaust fan which primarily serves to forcibly discharge air from the first accommodation space 15 to the outside of the housing 4, and is arranged to face the first air outlets 14a.

When the first axial flow fan 24 and the second axial flow fan 25 are driven, air is introduced into the front section of the first accommodation space 15 from outside the housing 4 through the first intake hole 12a. At the same time, air is discharged from the rear section of the first accommodation space 15 to the outside of the housing 4 through the first air outlets 14a.

As a result, as indicated by an arrow X in FIG. 2, the air flow is created inside the first accommodation space 15 from the front section towards the rear section, whereby the first and second information storage modules 17, 18, the card connection device 19, and the power module 20 are forcibly cooled.

The power module 20 generates more heat than the first and second information storage modules 17, 18 and the card connection device 19. Thus, the power module 20 is disposed in the downstream side of the air flow X in the first accommodation space 15. Accordingly, even when the power module 20 generates a large amount of heat, the first and second information storage modules 17, 18 and the card connection device 19 are prevented from being thermally affected by the power module 20.

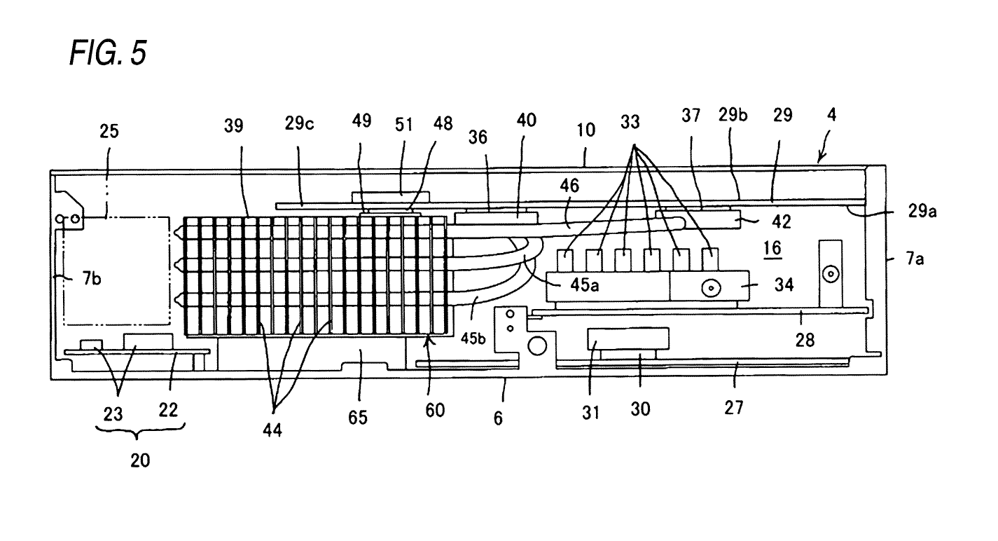

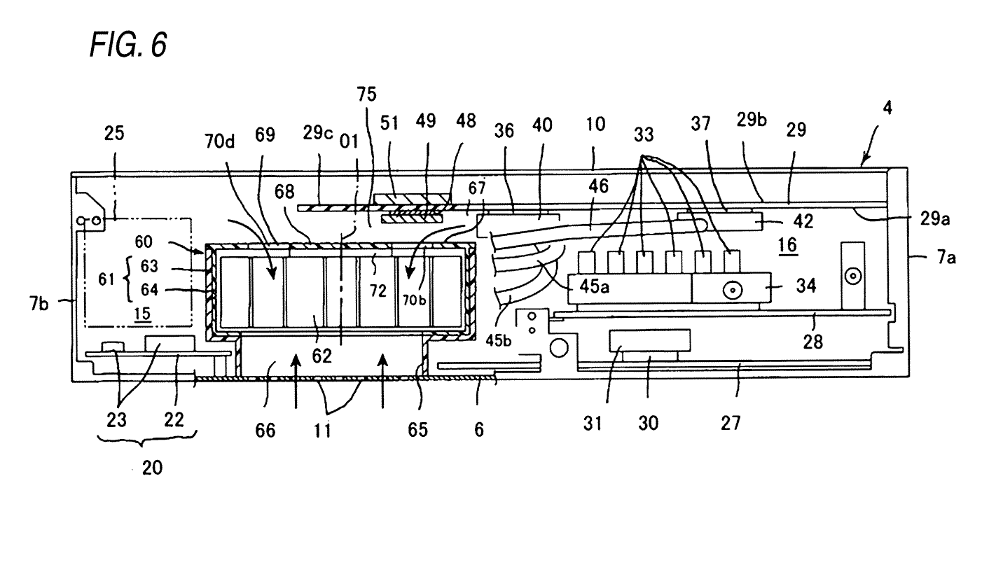

As shown in FIGS. 5 and 6, second to fourth circuit boards 27, 28, 29 are disposed in the second accommodation space 16 of the housing 4 so as to be stacked at intervals in the heightwise direction of the housing 4.

The second circuit board 27 is an image processing board, and is horizontally supported above the bottom wall 6 of the housing 4. The second circuit board 27 is mounted with a chip component 30 for image processing. A heat sink 31 is attached to the chip component 30.

The third circuit board 28 is a tuner board, and is horizontally supported above the second circuit board 27 via a bracket (not shown). The third circuit board 28 is mounted with six tuner modules 33 for receiving TV signals and one distributor 34 which is connected to the tuner modules 33.

The fourth circuit board 29 is a main board, and is horizontally supported above the third circuit board 28 via a bracket (not shown). The fourth circuit board 29 has a first surface 29a and a second surface 29b. The first surface 29a is arranged to face the third circuit board 28. The second surface 29b is located on the opposite side of the first surface 29a, and is arranged to face the top wall 10 of the housing 4. A high-performance processor 36 and an I/O controller 37 are mounted on the first surface 29a.

The high-performance processor 36 and the I/O controller 37 are examples of heat generating elements. According to one embodiment, the heat generated by the high-performance processor 36 and the I/O controller 37 is transferred to a heat sink 39 (a heat dissipating member), and is then forcibly dissipated from the heat sink 39 to the outside the housing 4.

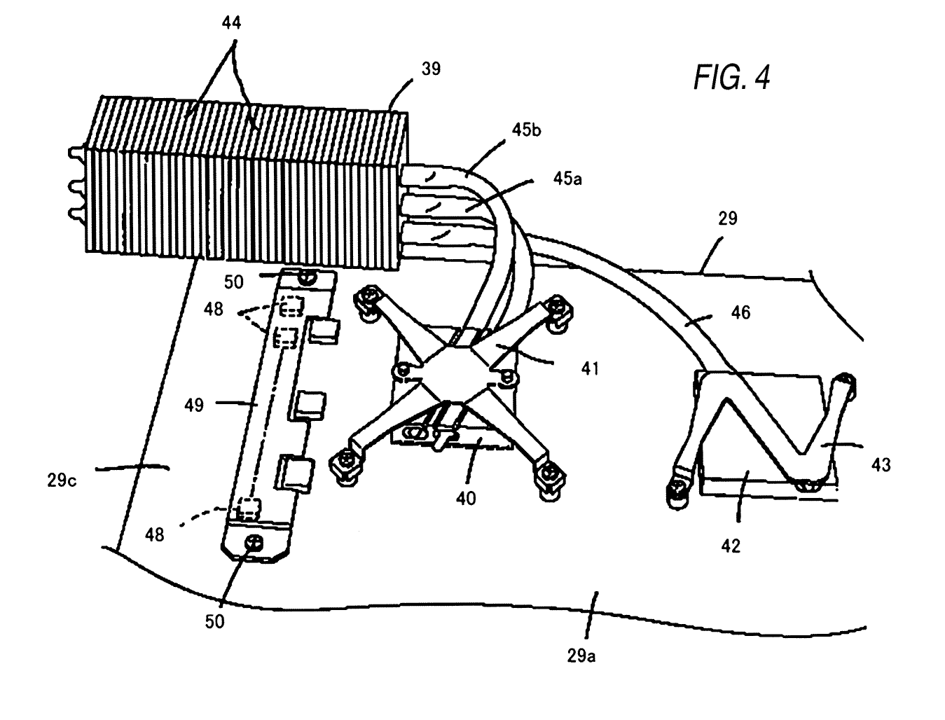

More specifically, as shown in FIGS. 4 to 6, a first heat receiving block 40 is thermally connected to the high-performance processor 36. The first heat receiving block 40 is made of a metal material having high thermal conductivity such as copper. The first heat receiving block 40 is held by the first surface 29a of the fourth circuit board 29 via a cruciform pressing spring 41. The pressing spring 41 presses the first heat receiving block 40 against the high-performance processor 36 with prescribed pressure.

Likewise, a second heat receiving block 42 is thermally connected to the I/O controller 37. The second heat receiving block 42 is made of a metal material having high thermal conductivity such as copper. The second heat receiving block 42 is held by the first surface 29a of the fourth circuit board 29 via an N-shaped pressing spring 43. The pressing spring 43 presses the second heat receiving block 42 against the I/O controller 37 with prescribed pressure.

The heat sink 39 has a plurality of heat radiation fins 44, which are arranged parallel to each other at intervals. Two heat pipes 45a, 45b are arranged to extend between the heat sink 39 and the first heat receiving block 40.

One end portion of each of the heat pipes 45a, 45b is fixed to the first heat receiving block 40 by, for example, crimping so as to be thermally connected to the first heat receiving block 40. The other end portion of each of the heat pipes 45a, 45b penetrates through the heat radiation fins 44, and is thermally connected to the heat radiation fins 44.

Accordingly, the heat generated by the high-performance processor 36 is transmitted to the first heat receiving block 40, and is then transferred from the first heat receiving block 40 to the heat sink 39 via the heat pipes 45a, 45b.

Likewise, a heat pipe 46 is arranged to extend between the heat sink 39 and the second heat receiving block 42. One end portion of the heat pipe 46 is fixed to the second heat receiving block 42 by, for example, crimping so as to be thermally connected to the second heat receiving block 42. The other end portion of the heat pipe 46 penetrates through, and is thermally connected to the heat radiation fins 44.

Accordingly, the heat generated by the I/O controller 37 is transmitted to the second heat receiving block 42, and is then transferred from the second heat receiving block 42 to the heat sink 39 via the heat pipe 46.

As shown in FIGS. 2 and 6, a fan 60 is disposed inside the second accommodation space 16 of the housing 4. The fan 60 includes a fan casing 61 and an impeller 62. The fan casing 61 has an outer casing 63 and an inner casing 64. The rear edge of a top plate 67 of the fan casing 61 and a rear opening of the outer casing 63 form an air outlet 73 of the fan 60. The air outlet 73 is opened toward the rear side of the housing 4 so as to be perpendicular to a first air inlet 66 and a second air inlet 69, and is disposed to face the heat sink 39 and the end portions of the heat pipes 45a, 45b, 46. According to this configuration, cooling air that is sent out from the fan 60 directly towards the heat sink 39 and the heat pipes 45a, 45b, 46, whereby the cooling efficiency can be increased.

The heat pipes 45a, 45b, 46 hold the heat sink 39 such that the heat sink 39 is placed near a rear end portion of the first surface 29a of the fourth circuit board 29. Therefore, when the fourth circuit board 29 is horizontally supported above the third circuit board 28, the heat sink 39 is disposed in a rear end part of the second accommodation space 16 of the housing 4 so as to face the second air outlets 14b of the housing 4.

As shown in FIGS. 4 to 6, according to one embodiment, the heat pipes 45a, 45b, 46 are connected to the heat sink 39 in a row. More specifically, the heat pipe 46 is connected to the heat sink 39 at a position that is closest to the first surface 29a of the fourth circuit board 29. The heat pipe 45a is connected to the heat sink 39 at a position that is second closest to the first surface 29a of the fourth circuit board 29. The heat pipe 45b is connected to the heat sink 39 at a position that is farthest from the first surface 29a of the fourth circuit board 29. That is, in the order of the heat pipe 45b, the heat pipe 45a and the heat pipe 46, a distance between a position of connection to the heat receiving block 40, 42 and the position of connection to the heat sink 39 becomes longer, and a slope thereof becomes gradual.

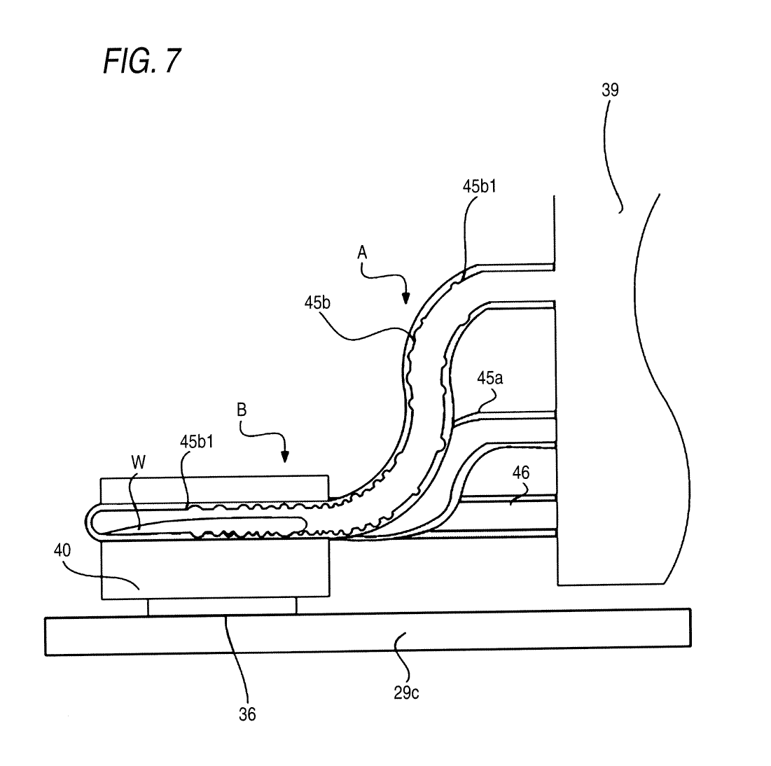

Next, configurations of the heat pipes 45a, 45b, 46 according to one embodiment will be described with reference to FIG. 7. FIG. 7 is an exemplary sectional view of the heat pipes 45a, 45b, 46.

A working fluid W is enclosed in each of the heat pipes 45a, 45b, 46. The working fluid W evaporates and vaporizes upon receipt of heat from the first heat receiving block 40 or the second heat receiving block 42. The vaporized working fluid W condenses and liquefies as it releases the heat to the heat sink 39. In this way, inside each of the heat pipes 45a, 45b, 46, the working fluid W circulates by repeating the evaporation and the liquefaction.

However, in a case in which a heat pipe is steeply sloped or in a case in which the length of the heat pipe itself is long, cooling efficiency may decrease due to stagnation of the working fluid circulation. In particular, where the position of the heat releasing portion is lower than the position of the heat receiving portion in a state in which a TV-received-associated apparatus is set in place, what is called a top-heat state may occur. As the slope of the heat pipe becomes steeper, the working fluid circulation becomes more likely to stagnate, which results in a remarkable decrease of the cooling efficiency.

In view of the above, according to one embodiment, wicks 45b1 are provided on an inner side of the heat pipe 45b having a steep slope, in order to suppress the stagnation of the circulation of the working fluid W. The wicks 45b1 provide a fluid capturing structure to temporarily hold the working fluid W. For example, the wicks 45b1 is made of a porous material or has projections that project from the inner surface of the heat pipe 45b. The wicks 45b1 serves to increase the surface area of the inner surface of the heat pipe 45b, and exerts capillary force to the working fluid W.

According to the embodiment described above, the heat pipe 45b having a large inclination has the fluid capturing structure to hold the operation fluid W. With the heat pipe 45b having this structure, even when the position of the heat releasing portion is lower than that of the heat receiving portion in a state in which the TV-received-associated apparatus 1 is set in place, stagnation of the circulation of the working fluid W is suppressed to prevent the cooling efficiency from remarkably being lowered.

As shown in FIG. 7, the wicks 45b1 may have a first region A and a second region B which is closer to the first heat receiving block 40 than from the first region A. The second region B has more pores than the first region A. That is, the second region B has a structure that is more adapted for holding of the working fluid W than the first region A. According to this configuration, even when the position of the heat releasing portion is lower than the position of the heat receiving portion, stagnation of the circulation of the working fluid W is suppressed more effectively to prevent the cooling efficiency from remarkably being lowered.

The upper limit of the rated temperature range of the high-performance processor 36 is higher than the upper limit of the rated temperature range of the I/O controller 37. According to one embodiment, the distance from the high-performance processor 36 to the heat sink 39 is shorter than the distance from the I/O controller 37 to the heat sink 39. That is, the lengths of the heat pipes 45a, 45b thermally connected to the high-performance processor 36 are shorter than the length of the heat pipe 46 thermally connected to the I/O controller 37 which generates a smaller amount of heat than the high-performance processor 36, whereby heat exchange efficiency can be made higher for the component that has a larger heat generation amount.

As shown in FIG. 6, the fourth circuit board 29 has an extension 29c which projects toward the first circuit board 22 than the second circuit board 27 and the third circuit board 28. The lower surface of the extension 29c of the fourth circuit board 29 is mounted with a plurality of field-effect transistors (FETs) 48. The FETs 48 are examples heat generating circuit components, and are located next to the first heat receiving block 40 so as to be arranged in line in the front-rear direction of the housing 4.

The lower surface of the extension 29c of the fourth circuit board 29 is also mounted with a heat dissipating plate 49 which is made of a metal material having high thermal conductivity such as aluminum. The heat dissipating plate 49 is configured and arranged to extend in the direction in which the FETs 48 are arranged, and is fixed to the fourth circuit board 29 with screws 50 at its respective ends in the longitudinal direction of the heat dissipating plate 49. The heat dissipating plate 49 is thermally connected to the FETs 48 so as to cover the FETs 48 from below, so that the heat dissipating plate 49 dissipates the heat generated by the FETs 48 toward an internal space of the housing 4.

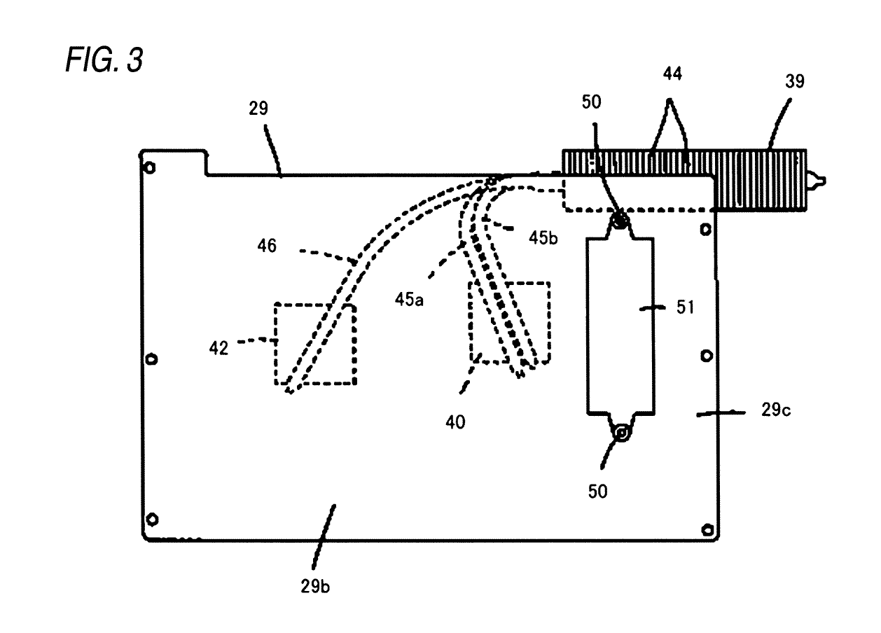

As shown in FIGS. 3 and 6, an upper surface of the extension 29c of the fourth circuit board 29 is mounted with a back plate 51 which is made of a metal material having high thermal conductivity such as aluminum. The back plate 51 is fixed to the fourth circuit board 29 with the screws 50. Thus, the fourth circuit board 29 is sandwiched between the back plate 51 and the heat dissipating plate 49. The back plate 51 reinforces, from above the fourth circuit board 29, the portion of the fourth circuit board 29 to which the heat dissipating plate 49 is attached.

The back plate 51 is thermally connected to the fourth circuit board 29 on a side opposite to the FETs 48. Therefore, a part of the heat generated by each FET 48 is transmitted to the back plate 51 indirectly, that is, via the fourth circuit board 29.

As such, the back plate 51 placed on the fourth circuit board 29 also has a function of to indirectly dissipate the heat generated by the FETs 48. By virtue of the back plate 51, the heat that is transmitted to the heat dissipating plate 49 is reduced, and the temperature increase of the heat dissipating plate 49 is suppressed.

As shown in FIGS. 2 and 6, the fan 60 is disposed in the second accommodation space 16 of the housing 4. The fan 60 sends a cooling air toward the heat sink 39, and is disposed between the bottom wall 6 of the housing 4 and the extension 29c of the fourth circuit board 29.

The fan 60 has the fan casing 61 and the impeller 62, and the fan casing 61 has the outer casing 63 and the inner casing 64. The outer casing 63 has a rectangular box shape that is opened at the top and on the rear side.

The outer casing 63 has a cylindrical duct portion 65 at the bottom. The duct portion 65 projects from the bottom of the outer casing 63 toward the bottom wall 6 of the housing 4, and its bottom end portion is fixed to the bottom wall 6 with a plurality of screws.

The duct portion 56 surrounds that portion of the bottom wall 6 which is formed with the air inlets 11. As such, the duct portion 56 constitutes the first air inlet 66 which communicates with the outside of the housing 4 via the air inlets 11.

The inner casing 64 is fitted in the outer casing 63 and has the top plate 67. The top plate 67 is attached to the top edges of the outer casing 63 so as to cover the top opening of the outer casing 63. The top plate 67 has an impeller attachment portion 68 and the second air inlet 69.

As shown in FIG. 2, the impeller attachment portion 68 is a central portion of the top plate 67. The second air inlet 69 has first to fourth openings 70a, 70b, 70c, 70d. The first to fourth openings 70a, 70b, 70c, 70d, each of which is curved like an arc, surround the impeller attachment portion 68. More specifically, the first to fourth openings 70a, 70b, 70c, 70d are arranged at intervals along a circle that is concentric with the impeller attachment portion 68.

As shown in FIG. 6, the impeller 62 is supported by the bottom surface of the impeller attachment portion 68 with a flat motor 72 interposed in between. The impeller 62 is disposed between the bottom of the outer casing 63 and the top plate 67 of the inner casing 64 with its rotation axis O1 extending in the vertical direction. Therefore, the first air inlet 66 and the second air inlet 69 are opposed to each other with the impeller 62 disposed between them and are arranged in the direction of the rotation axis O1 of the impeller 62.

As shown in FIG. 2, the rear edge of the top plate 67 of the fan casing 61 and the rear opening of the outer casing 63 constitute the air outlet 73. The air outlet 73 is formed near the rear plate 9 of the housing 4 so as to be perpendicular to the first air inlet 66 and the second air inlet 69, and is opposed to the heat sink 39.

When the impeller 62 is driven by the flat motor 72, air outside the housing 4 is taken into the rotation center portion of the impeller 62 through the air inlets 11 and the first air inlet 66 (indicated by arrows in FIG. 6). At the same time, air inside the housing 4 is taken into the rotation center portion of the impeller 62 through the first to fourth openings 70a, 70b, 70c, 70d of the second air inlet 69.

As shown in FIGS. 2 and 6, about a half of the fan 60 is located below the extension 29c of the fourth circuit board 29. In one embodiment, about a half of the first opening 70a, the second opening 70b and the third opening 70c of the second air inlet 69 of the fan 60 face a gap 75 between the extension 29c of the fourth circuit board 29 and the top plate 64 of the fan casing 61.

The heat dissipating plate 49 which is thermally connected to the FETs 48 also faces the gap 75, and is opposed to most of the second opening 70b and a part of the third opening 70c via the gap 75.

Of the second air inlet 69 of the fan 60, the remaining half of the first opening 70a and most of the fourth opening 70d are located in the housing 4 but do not overlap with the extension 29c of the fourth circuit board 29. In other words, the remaining half of the first opening 70a and most of the fourth opening 70d do not face the gap 75, and are opposed to the top wall 10 of the housing 4.

The fan 60 is disposed next to the second axial flow fan 25. When the second axial flow fan 25 is in operation, the air inside the housing 4 is suctioned by the second axial flow fan 25. As a result, as indicated by an arrow in FIG. 2, an air flow path 76 toward the second axial flow fan 25 is created inside the housing 4.

In one embodiment, of the second air inlet 69 of the fan 60, the remaining half of the first opening 70a and most of the fourth opening 70d are located in the air flow path 76 to take in the air that flows along the air flow path 76.

In the Set-top box 1 having the above configuration, the FETs 48 which are mounted on the fourth circuit board 29 generate heat during operation. A large part of the heat generated by each FET 48 is directly transmitted to the heat dissipating plate 49 and radiated from the heat dissipating plate 49 to the gap 75 between the fourth circuit board 29 and the top plate 67 of the fan casing 61. The remaining part of the heat generated by each FET 48 is transmitted, via the fourth circuit board 29, to the back plate 51 which is disposed on the back side of the FETs 48, and radiated to the inside space of the housing 4 from the back plate 51.

When the first and second axial flow fans 24, 25 are operated during use of the Set-top box 1, air outside the housing 4 is taken into the first accommodation space 15 of the housing 4 through the first intake hole 12a. Furthermore, the air inside the rear section of the first accommodation space 15 is sent out of the housing 4 through the first air outlets 14a, whereby the air flow path 76 toward the second axial flow fan 25 is created inside the housing 4.

When the fan 60 is operated during use of the Set-top box 1, air outside the housing 4 is taken into the rotation center portion of the impeller 62 through the air inlets 11 and the first air inlet 66 of the fan casing 61. At the same time, since the half of the first opening 70a, the second opening 70b, and the third opening 70c of the second air inlet 69 of the fan casing 61 face the gap 75 which is formed in the housing 4, the air in the gap 75 is taken into the rotation center portion of the impeller 62 through the first to third openings 70a, 70b, 70c. As a result, an air flow toward the second air inlet 69 is created in the gap 75.

The air that has been sectioned into the rotation center portion of the impeller 62 is sent toward the inside space of the fan casing 61 through the periphery of the impeller 62, and is then sent toward the heat sink 31 through the air outlet 73 of the fan casing 61. As a result, the heat generated by each of the high-performance processor 36 and the I/O controller 37 is emitted to outside the housing 4 being carried by the air that passes the heat sink 31.

According to one embodiment of the invention, the heat generated by each FET 48 and radiated to the gap 75 from the heat dissipating plate 49 is carried by an air flow created in the gap 75 and is taken into the first to third openings 70a, 70b, 70c of the second air inlet 69.

Furthermore, since most of the second opening 70b and part of the third opening 70c are opposed to the heat dissipating plate 49 via the gap 49, the heat generated by each FET 48 and radiated from the heat dissipating plate 49 is taken into the fan casing 61 together with the air through the second and third openings 70b, 70c before being dispersed over the gap 75.

A half of the first opening 70a and the fourth opening 70d of the second air inlet 69 are formed in the housing 4 so as not to face the gap 75 and to be located in an air flow path 76 toward the second axial flow fan 25.

Therefore, in addition to the air in the gap 75, the second air inlet 69 also positively takes in a part of the air flowing along the air flow path 76. Therefore, no strong resistance is likely to occur when air is taken in through the second air inlet 69.

As a result, good ventilation is attained in the housing 4 including the gap 75, which prevents a phenomenon that the heat that is radiated from the heat dissipating plate 49 stays in the gap 75. Therefore, the heat dissipation performance of the FETs 48 can be enhanced and overheating and an operation failure of the FETs 48 can be prevented in a reliable manner.

The invention is not limited to the embodiment described above, and various changes and modifications can be made therein without departing from the spirit and scope of the invention.

For example, although in the embodiment the heat dissipating plate 49 which is thermally connected to the FETs 48 is opposed to the second and third openings 70b and 70c of the second air inlet 69, the invention is not limited to such a case. For example, the FETs 48 may be exposed to the gap 75 (the heat dissipating plate 49 is omitted) and opposed to the second and third openings 70b, 70c of the second air inlet 69.

Furthermore, the heat generating circuit component to which the heat dissipating plate 49 is connected is not limited to the FET and may be other circuit components such as a semiconductor package.

In addition, an electronic apparatus according to an embodiment of the invention is not limited to the Set-top box, and may other apparatuses such as a personal computer or a server.

What is claimed is:

1. An electronic apparatus comprising:
a housing;
a heat dissipating member disposed inside the housing;
a circuit board disposed inside the housing;
a first heat generating element mounted on the circuit board;
a second heat generating element mounted on the circuit board;
a first heat pipe; and
a second heat pipe,
wherein the first heat pipe comprises:
a first heat receiving portion thermally connected to the first heat generating element; and
a first heat releasing portion thermally connected to the heat dissipating member, and
wherein the second heat pipe comprises:
a second heat receiving portion thermally connected to the second heat generating element;
a second heat releasing portion thermally connected to the heat dissipating member at a position that is more distant from the circuit board than a position at which the first heat releasing portion of the first heat pipe is thermally connected to the heat dissipating member; and
a fluid capturing structure configured to temporarily hold a working fluid enclosed inside the second heat pipe.

2. The apparatus of claim 1 further comprising a fan disposed inside the housing and having an air outlet to send a cooling air toward the heat dissipating member,
wherein the first heat pipe, the second heat pipe and the fan are arranged such that the air outlet faces at least a part of the first heat releasing portion and a part of the second heat releasing portion.

3. The apparatus of claim 2, wherein the second heat generating element is more distant from a bottom wall of the housing than the second heat releasing portion of the second heat pipe.

4. The apparatus of claim 3, wherein the fan has an air inlet opposed to the bottom wall of the housing to take in air from outside the housing, and
wherein the first heat releasing portion of the first heat pipe is more distant from the bottom wall of the housing than the second heat releasing portion of the second heat pipe.

5. The apparatus of claim 4, wherein an upper limit of a rated temperature range of the second heat generating element is higher than an upper limit of a rated temperature range of the first heat generating element.

6. The apparatus of claim 1, wherein a distance between the first heat receiving portion and the first heat releasing portion of the first pipe is longer than a distance between the second heat receiving portion and the second heat releasing portion of the second heat pipe.

7. The apparatus of claim 1, wherein the fluid capturing structure has a first region formed with pores, and a second region formed with more pores than the first region, and wherein the second region is closer to the second heat receiving portion than the first region.

8. An electronic apparatus comprising:
a housing;
a heat dissipating member disposed inside the housing;
a first heat generating element mounted on the circuit board;
a second heat generating element mounted on the circuit board;
a first heat pipe; and
a second heat pipe,
wherein the first heat pipe comprises:
a first heat receiving portion thermally connected to the first heat generating element; and
a first heat releasing portion thermally connected to the heat dissipating member, and
wherein the second heat pipe comprises:
a second heat receiving portion thermally connected to the second heat generating element;
a second heat releasing portion thermally connected to the heat dissipating member; and
a fluid capturing structure configured to temporarily hold a working fluid enclosed inside the second heat pipe.

9. The apparatus of claim 8 further comprising a fan disposed inside the housing and having an air outlet to send a cooling air toward the heat dissipating member,
wherein the first heat pipe, the second heat pipe and the fan are arranged such that the air outlet faces at least a part of the first heat releasing portion and a part of the second heat releasing portion.

10. The apparatus of claim 8, wherein a distance between the first heat receiving portion and the first heat releasing portion of the first pipe is longer than a distance between the second heat receiving portion and the second heat releasing portion of the second pipe.

11. The apparatus of claim 8 further comprising a pressing member opposed to the first heat receiving portion of the first heat pipe to press the heat receiving portion against the first heat generating element, wherein a gap is provided between the pressing member and the second heat pipe.
